(19) United States
(12) Patent Application Publication
(10) Pub. No.: US 2026/0324347 A1
(43) Pub. Date: Oct. 15, 2026

(54) METHOD OF TEACHING SUBSTRATE TRANSFER DEVICE, AND SUBSTRATE PROCESSING APPARATUS

(71) Applicant: Tokyo Electron Limited, Tokyo (JP)

(72) Inventors: Kosuke KINOSHITA, Fuchu City (JP); Takashi SUGIMOTO, Nirasaki City (JP)

(21) Appl. No.: 19/634,417

(22) Filed: Mar. 31, 2026

(30) Foreign Application Priority Data
Apr. 9, 2025 (JP) 2025-064146

(51) Int. Cl. H10P 72/00; H10P 72/30; H10P 72/76

(52) U.S. Cl. CPC H10P 72/0606; H10P 72/3302; H10P 72/7612; H10P 72/7624

(57) ABSTRACT

A method of teaching a substrate transfer device includes: executing a cycle with respect to each of at least three reference directions set so as to extend in different directions from a center toward a periphery of a placement surface of a stage, the cycle including: tilting at least one of the placement surface or the substrate such that the periphery is lower in height position than the center along one of the reference directions; lowering at least three lifting pins to deliver the substrate to the stage; raising the lifting pins such that the transfer arm receives the substrate; and detecting a position of the substrate; determining a target position based on results of detecting positions of the substrate after being moved along all of the reference directions; and setting the target position to a set position of the transfer arm.

### CROSS-REFERENCE TO RELATED APPLICATION

This application is based upon and claims the benefit of priority from Japanese Patent Application No. 2025-064146, filed on Apr .9, 2025, the entire contents of which are incorporated herein by reference.

### TECHNICAL FIELD

The present disclosure relates to a method of teaching a substrate transfer device, and a substrate processing apparatus.

### BACKGROUND

In a manufacturing process of semiconductor devices, various processes, such as forming a metal film, are performed on a semiconductor wafer, which is a substrate. Such processes may be performed in a st ate where the wafer is placed on a stage provided inside a processing container.

Patent Document 1 discloses an adhesion processing apparatus for improving adhesion between a resist and a wafer, in which a hot plate configured as a substrate stage on which the wafer is placed is shown. In order to place the wafer on the hot plate, a transfer arm or the like disposed outside the adhesion processing apparatus locates the wafer above the hot plate while supporting the wafer. Subsequently, support pins protrude from a surface of the hot plate to receive the wafer from the transfer arm, and then descend to place the wafer on the hot plate.

### Prior Art Documents

### Patent Documents

Patent Document 1: Japanese Patent No. 2,885,502

### SUMMARY

According to one embodiment of the present disclosure, there is provided a method of teaching a substrate transfer device including a transfer arm configured to transfer a substrate, a drive mechanism configured to move the transfer arm, and a drive controller configured to control the drive mechanism such that the transfer arm moves to a preset set position. When the substrate is transferred by the transfer arm to a stage including a placement surface on which the substrate is placed, an edge portion is provided so as to protrude from the placement surface along a periphery of the placement surface, and at least three lifting pins configured to move upward and downward with respect to the placement surface are provided and configured to deliver the substrate with respect to the transfer arm while holding the substrate, the method includes: executing a cycle with respect to each of at least three reference directions which are set so as to extend in different directions from a center of the placement surface toward the periphery of the placement surface, the cycle including: (a) an operation of tilting at least one of the placement surface or the substrate held by the at least three lifting pins such that, along one reference direction selected from the at least three reference directions, a height position of the periphery is lower than a height position of the center; (b) an operation of lowering the at least three lifting pins to deliver the substrate to the stage; (c) an operation of, after the substrate delivered to the stage moves onto the placement surface along the one reference direction and reaches an inner periphery of the edge portion, raising the at least three lifting pins such that the transfer arm receives the substrate; and (d) an operation of detecting a position of the substrate received from the stage by the transfer arm; determining a target position at which the substrate is to be delivered from the transfer arm to the stage, based on results of detecting positions of the substrate after being moved along all of the at least three reference directions; and setting the target position to the set position of the transfer arm for the drive controller.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view illustrating a substrate processing apparatus according to a first embodiment.

FIG. 2 is a plan view showing a holder of a transfer mechanism.

FIG. 3 is a vertical sectional side view of a vacuum transfer chamber and a film formation module.

FIG. 4 is a block diagram showing the substrate processing apparatus and a controller.

FIG. 5 is a plan view showing a holder that holds a substrate, and a line sensor.

FIG. 6 is a vertical sectional side view showing the film formation module.

FIG. 7A is a vertical sectional side view showing the holder and lifting pins during substrate placement.

FIG. 7B is a vertical sectional side view showing the holder and the lifting pins during the substrate placement.

FIG. 8A is a flowchart showing cyclic operations performed in a delivery destination position determination operation in the first embodiment.

FIG. 8B is a diagram showing a procedure of the delivery destination position determination operation.

FIG. 9A is a partial vertical sectional side view of a stage, which illustrates the delivery destination position determination operation.

FIG. 9B is a partial vertical sectional side view of the stage, which illustrates the delivery destination position determination operation.

FIG. 9C is a partial vertical sectional side view of the stage, which illustrates the delivery destination position determination operation.

FIG. 10A is a plan view of the stage and the substrate, which illustrates the delivery destination position determination operation.

FIG. 10B is a plan view of the stage and the substrate, which illustrates the delivery destination position determination operation.

FIG. 10C is a plan view of the stage and the substrate, which illustrates the delivery destination position determination operation.

FIG. 10D is a plan view of the stage and the substrate, which illustrates the delivery destination position determination operation.

FIG. 11 is a plan view showing a modification of the substrate processing apparatus.

FIG. 12 is a vertical sectional side view showing a film formation module according to a second embodiment.

FIG. 13A is a partial vertical sectional side view of a stage, which illustrates an operation of specifying a delivery destination position in the second embodiment.

FIG. 13B is a partial vertical sectional side view of the stage, which illustrates the operation of specifying the delivery destination position in the second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

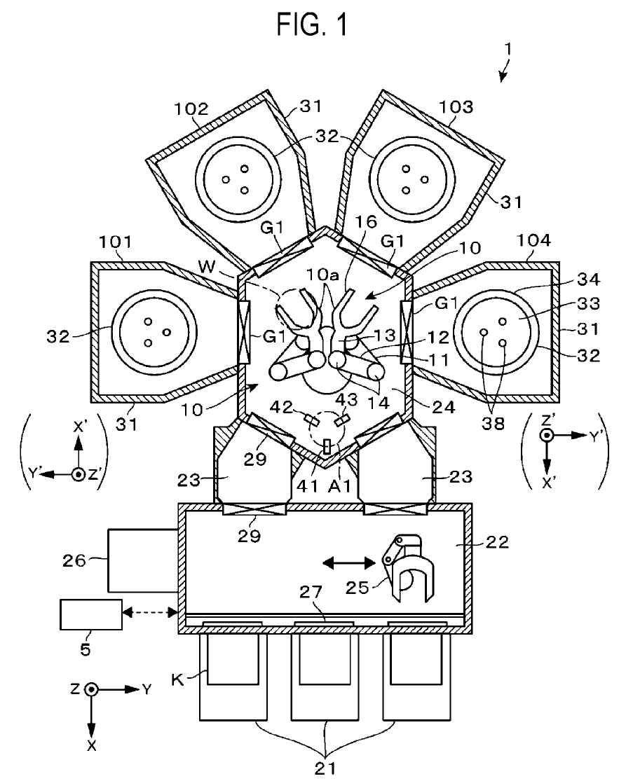

FIG. 1 is a plan view illustrating a substrate processing apparatus according to a first embodiment. A substrate processing apparatus 1 is configured as a multi-chamber vacuum processing system including film formation modules 101 to 104 for forming films on a substrate W, and a vacuum transfer chamber (transfer module) 24 for transferring the substrate W to the film formation modules 101 to 104.

The substrate processing apparatus 1 includes, for example, an atmospheric-pressure transfer chamber 22 whose interior is maintained in an atmospheric environment. A load port 21 is provided in front of the atmospheric-pressure transfer chamber 22 to deliver the substrate W to and from a transfer container K in which the substrate W is accommodated. An opening/closing door 27, which is open when loading and unloading the substrate W to and from the transfer container K, is provided on a front wall of the atmospheric-pressure transfer chamber 22. Further, a transfer mechanism 25 for transferring the substrate W is provided inside the atmospheric-pressure transfer chamber 22.

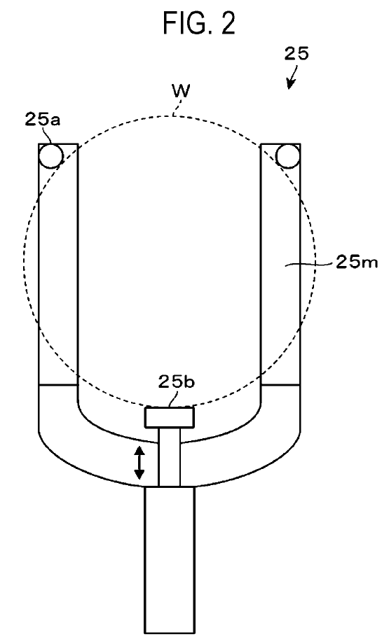

FIG. 2 is a plan view showing a holder 25m of the transfer mechanism 25 in a state of holding the substrate W. The transfer mechanism 25 has a structure similar to that of a transfer mechanism 10 to be described later, and includes a placement surface for the substrate W, two regulating protrusions 25a provided on a distal end side of the placement surface, and a pressing portion 25b provided on a proximal end side of the placement surface, all of which are formed on an upper surface of a U-shaped holder 25m. This configuration provides an edge grip function. The transfer mechanism 25 is configured such that, in a state where the substrate W is delivered onto the placement surface, the pressing portion 25b is moved toward the regulating protrusions 25a to regulate a holding position of the substrate W by the regulating protrusions 25a and the pressing portion 25b. In this manner, by holding the substrate W in a state pressed against the two regulating protrusions 25a, the transfer mechanism 25 holds the substrate W with, for example, the center of the substrate W positioned at a preset position such as the center of the holder 25m in a plan view.

Further, as viewed from the load port 21, an alignment chamber 26 is provided on a left sidewall of the atmospheric-pressure transfer chamber 22 to adjust an orientation and eccentricity of the substrate W. In the alignment chamber 26, the orientation of the substrate W and a transfer position of the substrate W to the transfer mechanism 25 are determined with reference to a notch or an orientation flat (not shown) formed at a peripheral portion of the substrate W. For example, when determining the orientation of the substrate W based on the notch, the alignment chamber 26 sets a radial direction passing through a tip of a V-shaped cutout of the notch to 0°, and the transfer mechanism 25 receives the substrate W such that the center of the substrate W is positioned at the preset position.

Two load lock chambers 23, which are arranged side by side, are connected to a wall surface opposite the load port 21 as viewed from the atmospheric-pressure transfer chamber 22. Each load lock chamber 23 has a function of switching an internal atmosphere thereof between an atmospheric pressure atmosphere and a vacuum atmosphere while accommodating the substrate W. The vacuum transfer chamber 24 is disposed on a rear side of the load lock chambers 23 as viewed from the atmospheric-pressure transfer chamber 22. Each load lock chamber 23 is connected to the atmospheric-pressure transfer chamber 22 and the vacuum transfer chamber 24 via respective gate valves 29.

An exhaust mechanism (not shown) is connected to the vacuum transfer chamber 24 so that an internal space of the vacuum transfer chamber 24 is maintained in a vacuum atmosphere. For example, four film formation modules 101 to 104 are connected to a sidewall of the vacuum transfer chamber 24. Further, for example, line sensors 41 to 43 and two transfer mechanisms 10 are provided in the vacuum transfer chamber 24. Each transfer mechanism 10 delivers the substrate W between the film formation modules 101 to 104 and the load lock chambers 23.

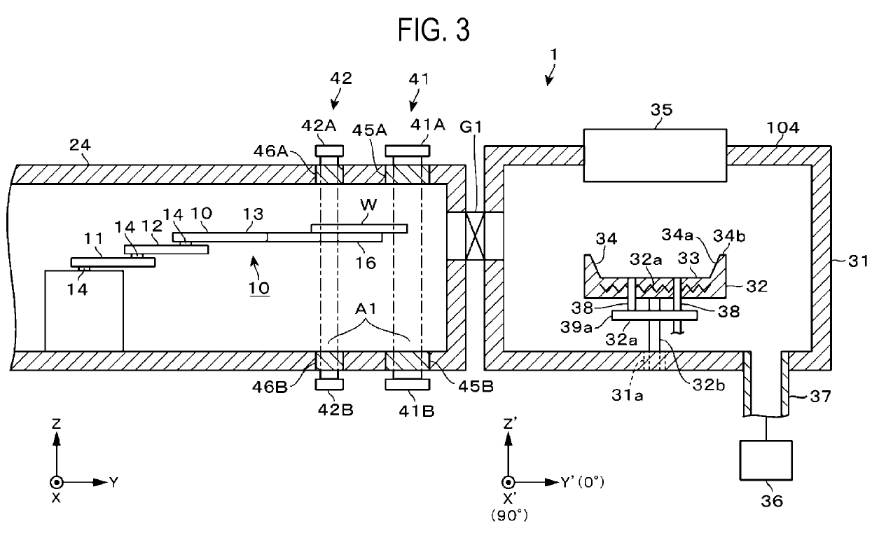

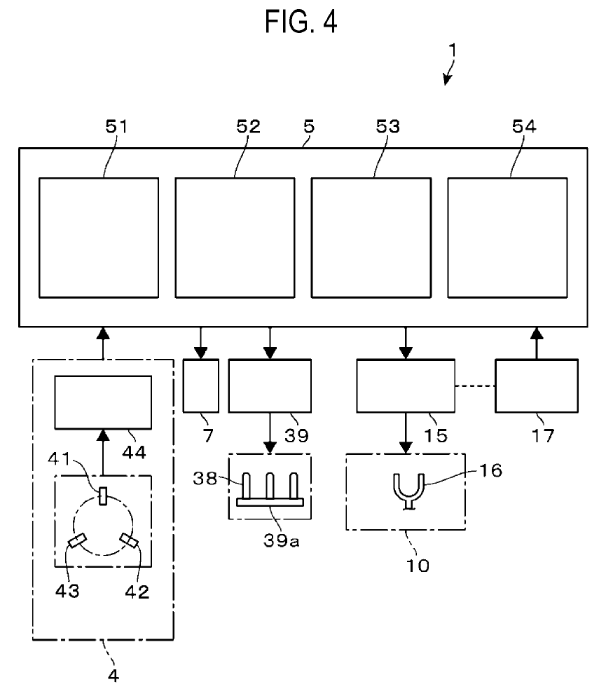

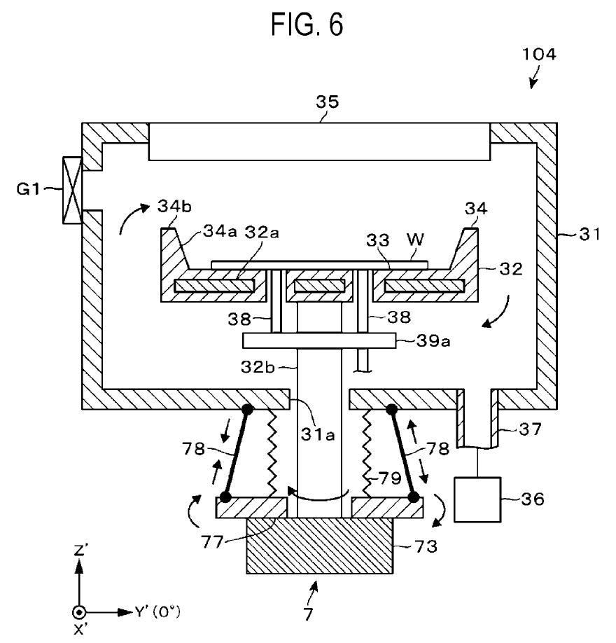

FIG. 3 is a vertical sectional side view of the vacuum transfer chamber 24 and the film formation module 104, in which a tilting mechanism 7 (FIG. 6) to be described later is omitted. FIG. 4 is a block diagram showing the substrate processing apparatus 1 and a controller 5. In FIG. 3, the line sensors 41 to 43 arranged near the load lock chamber 23 in the vacuum transfer chamber 24 of FIG. 1 are illustrated on the side of the film formation module 104 for the sake of convenience in description, and only two line sensors 41 and 42 are shown.

Each transfer mechanism 10 includes a transfer arm 10a configured as an articulated arm. For example, the transfer arm 10a includes a lower arm member 11, a middle arm member 12, an upper arm member 13, and rotation shafts 14 respectively provided on base sides of the arm members 11 to 13. Each rotation shaft 14 is connected to a respective rotation mechanism (not shown) and individually rotates to rotate the arm members 11 to 13. By combining these operations, the upper arm member 13 may move along a desired trajectory while performing rotational movement and linear movement. A holder 16 for holding the substrate W to be transferred is provided on a distal end side of the upper arm member 13.

The transfer arm 10a may include an extension/contraction mechanism, and the upper arm member 13 may be extended or contracted to increase or decrease a linear movement distance. Such an extension/contraction mechanism and a rotation mechanism constitute a drive mechanism for the transfer arm 10a. A pulse encoder 17 (FIG. 4) is connected to a motor (not shown) that drives the drive mechanism. The transfer arm 10a is connected to a drive controller 15. The drive controller 15 manages coordinates for specifying a position of the holder 16 (hereinafter also referred to as "drive-system coordinates," illustrated as a Z-Y-Z coordinate system in FIGS. 1 and 3) and controls the rotation mechanisms and the like so as to move the holder 16 to a set position to be described later.

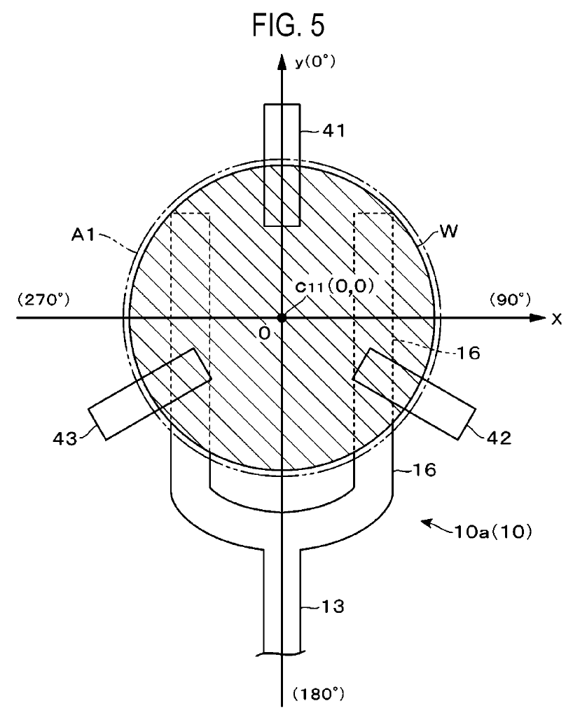

The holder 16 is provided on the distal end side of the upper arm member 13 and is configured to transfer the substrate W while holding the substrate W in a horizontal posture. As shown in FIG. 5 to be described later, the holder 16 has a U shape that opens bifurcately toward a distal end when viewed from a proximal end side of the upper arm member 13 in a plan view. The holder 16 may horizontally support the substrate W by placing the substrate W in a holding region including an upper surface of the holder 16. The holding region is configured to effectively suppress positional deviation of the substrate W in a central region thereof so as to appropriately hold the substrate W. The substrate W appropriately held in the holding region is arranged such that a center C of the substrate W coincides with a center of the holding region. Hereinafter, such a position at which the substrate W may be appropriately held may be referred to as an "appropriate holding position."

The holder 16 is managed by the drive controller 15 and the pulse encoder 17 such that a central position of the holding region is represented in, for example, a polar coordinate format (r, θ) with the rotation shaft 14 of the lower arm member 11 as an origin. This polar coordinate system is correlated with the drive-system coordinates of the drive controller 15. The transfer mechanism 10 configured as above may move the holder 16 to a desired position on the drive-system coordinates.

As shown in FIGS. 1, 3, and 5, three line sensors 41 to 43 are configured to detect a position of the substrate W held by the holder 16. The line sensors 41 to 43 include light-emitting portion 41A to 43A and light-receiving portion 41B to 43B, which are paired, respectively. The light-emitting portions 41A to 43A and the light-receiving portions 41B to 43B are provided on, for example, a ceiling side and a floor side of a housing of the vacuum transfer chamber 24 so as to face each other in a vertical direction, respectively. Specifically, the light-emitting portions 41A to 43A are provided on upper surfaces of light-transmitting windows 45A to 47A made of, for example, quartz, and provided on a ceiling portion of the vacuum transfer chamber 24. On the other hand, the light-receiving portions 41B to 43B are provided on lower surfaces of light-transmitting windows 45B to 47B made of, for example, quartz, and provided on a floor portion of the vacuum transfer chamber 24 so as to face the light-emitting portions 41A to 43A.

FIG. 5 is a plan view showing the holder 16 that holds the substrate W, and the line sensors 41 to 43. In FIG. 5, an xy coordinate system is a relative coordinate system in which an origin is set at a center of a measurement region A1 to be described later, and a y-axis direction is set as a direction toward which 0° of the substrate W faces when the substrate W aligned in the alignment chamber 26 is appropriately held in the holding region of the holder 16. The light-emitting portions 41A to 43A and the light-receiving portions 41B to 43B of the line sensors 41 to 43 are disposed to be spaced apart from each other at positions corresponding to a peripheral edge of the measurement region A1 in a plan view. Each of the light-emitting portion 41A to 43A is configured to emit light in a band-shaped region extending from an inner side to an outer side of the measurement region A1, and each of the light-receiving portion 41B to 43B receives the emitted light at a position corresponding to the band-shaped region. With this configuration, when the holder 16 holding the substrate W in the holding region is disposed in the measurement region A1, the line sensors 41 to 43 may detect positions of three different points along a peripheral edge of the substrate W within the band-shaped region. A position calculator 44 (FIG. 4) connected to the line sensors 41 to 43 calculates a position (x, y) of the center c of the substrate W from the detected positions of the three points. The position of the measurement region A1 is stored in advance in the drive controller 15.

By using the line sensors 41 to 43 provided in the band-shaped manner, even when the substrate W is held by the holder 16 in a state deviated from the appropriate holding position, a central position of the substrate W in that state may be calculated. The position calculator 44 constitutes a position detector (position detection mechanism) 4 together with the line sensors 41 to 43 (FIG. 4).

In this example, the film formation modules 101 to 104 are configured to form the same metal film. A configuration of the film formation module 104 will be briefly described as a representative of the film formation modules 101 to 104. As shown in FIGS. 1 and 3, the film formation module 104 is constituted by a processing container 31 connected to the housing of the vacuum transfer chamber 24 via a gate valve G1. The processing container 31 is formed with a loading/unloading opening for loading and unloading the substrate W therethrough. The gate valve G1 opens and closes the loading/unloading opening. When the gate valve G1 is closed, the processing container 31 is hermetically sealed. A stage 32 is provided inside the processing container 31 at a rear position as viewed from the gate valve G1. In the first embodiment, when loading the substrate W via the loading/unloading opening, a direction of 0° of the substrate W is oriented toward a leading end in a traveling direction.

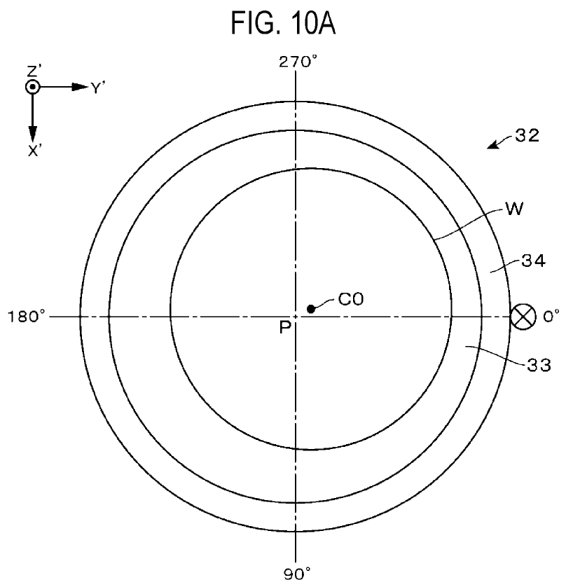

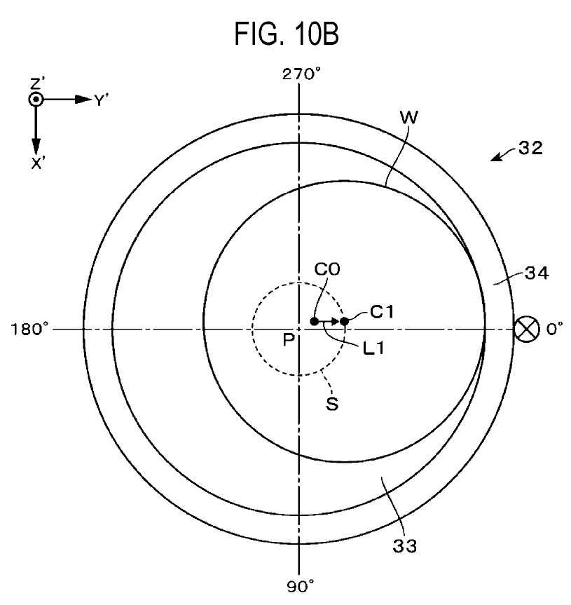

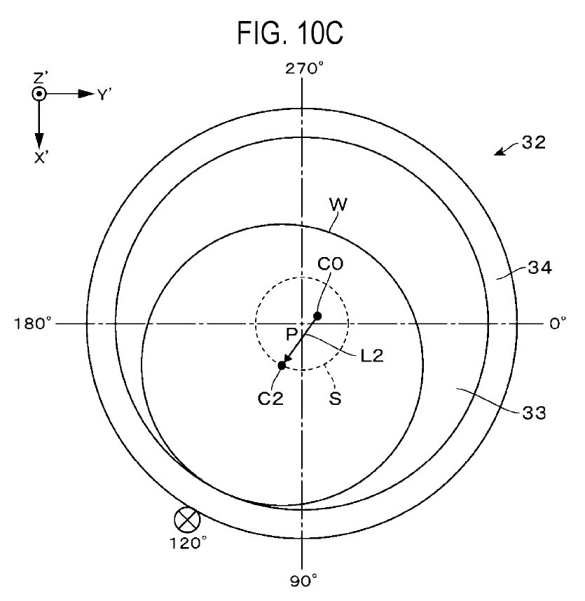

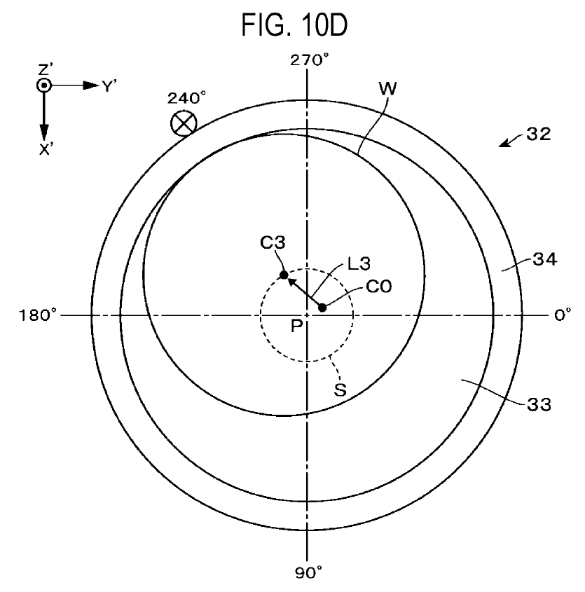

Further, sub-coordinates (X'-Y'-Z' coordinate system) illustrated together in FIGS. 1 and 3 are set for each of the film formation modules 101 to 104. Each sub-coordinate is set such that a radial direction corresponding to 0° set for the substrate W loaded into the film formation modules 101 to 104 coincides with a Y'-axis direction. For visibility, the sub-coordinates are illustrated with offsets in the drawings, but an origin thereof is set at a position that coincides with a center (C0) of the substrate W held by the holder 16 in a state placed at an "initial set position" to be described later (FIG. 10A). For the sake of convenience in illustration, FIG. 1 shows sub-coordinate systems for two film formation modules 101 and 104, but the remaining film formation modules 102 and 103 are also each assigned their own respective sub-coordinate systems corresponding to their directions of connection to the vacuum transfer chamber 24. In the example shown in FIGS. 1 and 3, axis directions of the drive-system coordinates (X-Y-Z coordinate system) set for the drive controller 15 of the transfer mechanism 10 coincide with axis directions of the sub-coordinates (X'-Y'-Z' coordinate system) set for the film formation module 104.

As shown in FIG. 3, a shower head 35 for supplying a processing gas is provided on a ceiling portion of the processing container 31 so as to face the stage 32. The processing gas is supplied into the processing container 31 from a gas supply system (not shown) via the shower head 35. A through-hole 31a and an exhaust port are formed in a bottom portion of the processing container 31. An exhaust pipe 37 provided with a vacuum pump 36 is connected to the exhaust port.

A support 32b that supports the stage 32 is inserted through the through-hole 31a formed in the bottom portion of the processing container 31. An upper end of the support 32b is disposed inside the processing container 31, and other portions thereof are disposed outside the processing container 31 (FIG. 6). The support 32b is attached to the bottom portion of the processing container 31 via the tilting mechanism 7. Normally, the support 32b is arranged in an upright state with respect to the bottom portion of the processing container 31, but may be tilted in various directions from the upright posture by the tilting mechanism 7, which will be described later. The stage 32 supported by the support 32bmay be tilted in conformity to a tilt of the support 32b. As a result of this operation, a flat placement surface 33 formed on an upper surface of the stage 32 may also be tilted from a horizontal posture toward a predetermined reference direction. Here, the "reference direction" refers to a direction (radial direction) set so as to extend from a center of the placement surface 33 toward a periphery of the placement surface 33. In this case, "tilting the placement surface 33 toward the reference direction" refers to a state in which, when viewed along the set reference direction, a height position of a periphery of the placement surface 33 is lower than a height position of a center thereof.

FIG. 6 is a vertical sectional side view of the film formation module 104, which illustrates a configuration and operation of the tilting mechanism 7. The tilting mechanism 7 is configured to tilt the support 32b. The support 32b is provided with various wirings (not shown) arranged to supply power to components around the stage 32. When an electrostatic chuck for electrostatically attracting the substrate W is provided on the stage 32, a direct current voltage applied to the electrostatic chuck is supplied via the wiring.

The tilting mechanism 7 includes a base member 77, a plurality of (for example, six) actuators 78 (only two are shown in FIG. 6), and a bellows 79. The base member 77 is attached to a lower end of the support 32b via a vacuum seal 73 and is configured to be movable integrally with the stage 32. For example, the base member 77 has a through-hole having a diameter larger than that of the lower end of the support 32b. The lower end of the support 32b is attached to the vacuum seal 73 that is airtightly fixed to a lower surface of the base member 77 via the through-hole. With this structure, the base member 77 is connected to the stage 32 via the vacuum seal 73 and the support 32b, and may swing integrally with the stage 32.

The plurality of actuators 78 connect the bottom portion of the processing chamber 31 and the base member 77, respectively, and are arranged in parallel around the support 32b while being spaced apart from one another. Upper and lower ends of each actuator 78 are connected to the bottom portion of the processing container 31 and the base member 77 via universal joints, respectively. Each actuator 78 is configured to be extendable and contractible along an axial direction thereof. By appropriately extending or contracting each actuator 78, a distance between the bottom portion of the processing container 31 and the base member 77 is varied. As a result, the base member 77, which is parallel to the bottom portion of the processing container 31 when the actuators 78 are not extended or contracted, may be appropriately tilted in various directions, so that the stage 32 may be correspondingly tilted in the same direction as the base member 77. The tilting mechanism 7 configured as described above appropriately adjusts the extension and contraction of the plurality of actuators 78 based on a tilt angle toward a preset direction (reference direction), thereby tilting the support 32b and the stage 32.

At this time, when the actuators 78 that have been extended or contracted tilt around an axis of the support 32b, the base member 77 may rotate and the stage 32 may be tilted in a position deviated from the preset direction. When such a phenomenon occurs, in order to correct an influence of rotation of the base member 77, a rotation drive mechanism (not shown) capable of independently rotating the support 32b may be provided, for example, between the vacuum seal 73 and the base member 77 or below the vacuum seal 73. With this rotation drive mechanism, the support 32b is rotated in a direction opposite to the rotation of the base member 77 to correct the influence of the rotation of the base member 77. Accordingly, the stage 32 may be accurately tilted in the preset direction.

Positions and tilts of the stage 32 adjusted by the plurality of actuators 78 may be specified by detecting positions and tilts of the base member 77 using various detection means. Examples of such detection means may include a linear encoder, a gyro sensor, a three-axis acceleration sensor, a laser tracker, and the like.

As described above, the tilting mechanism 7 according to the present embodiment includes the plurality of actuators 78 provided between the bottom portion of the processing container 31 and the base member 77 that is movable integrally with the stage 32. Accordingly, for example, when tilting the stage 32 with respect to the reference direction, for example, the Y'-axis direction in FIG. 6, an actuator 78 located in the reference direction is extended, and an actuator 78 located in a direction opposite to the reference direction is contracted, whereby the base member 77, which is provided parallel to the X'–Y' plane, is tilted in a rotational direction about the X' axis. As a result, the support 32b that had been erected in a vertical direction is tilted toward a rotation direction about the Y' axis in conjunction with the tilted base member 77. The stage 32 supported at a distal end of the support 32b is likewise tilted toward a rotation direction about the X' axis, thereby tilting the placement surface 33 along the reference direction of the Y'-axis direction. As a result, in the reference direction (Y'-axis direction) of the placement surface 33, a height position of a periphery of the placement surface 33 may be made lower than a height position of a center thereof. In this manner, the tilting mechanism 7 may tilt the placement surface 33 toward any of three reference directions along the X'-Y' plane, for example, a Y'-axis direction passing through the X'-Y' plane, and directions offset from the Y' axis by 120° and 240°.

The bellows 79 is provided so as to surround the support 32b, and upper and lower ends thereof are connected to the bottom portion of the processing container 31 and the base member 77, respectively. Accordingly, the bellows 79 airtightly seals a space between the bottom portion of the processing container 31 and the base member 77. The bellows 79 is configured to be extendable and contractible with movement of the base member 77. In the film formation module 104, even when the base member 77 is tilted, the bellows 79 expands and contracts, thereby preventing ambient air from flowing into the processing container 31 via the space between the bottom portion of the processing container 31 and the base member 77 and via the through-hole 31a.

The stage 32 configured to be tilted by the tilting mechanism 7 is disposed inside the processing container 31 of the film formation module 104. As shown in FIGS. 3 and 6 to be described later, a heater 32a, which is a resistance heating element, is embedded in the stage 32. An upper surface of the stage 32 is formed with a placement surface 33 for placing the substrate W, and an edge portion 34 is provided so as to protrude from the placement surface 33 along a periphery of the placement surface 33. The placement surface 33 is a circular surface larger than a back surface of the substrate W, and is, for example, a smooth surface having relatively small surface roughness.

The edge portion 34 is formed in an annular shape so as to be concentric with the placement surface 33. An upper end portion 34b of the edge portion 34 is flat, and a tapered surface 34a that gradually lowers from the upper end portion 34b toward the placement surface 33 is formed on an inner circumferential side facing the placement surface 33. Accordingly, the tapered surfaces 34a and the upper end portion 34b that constitute the edge portion 34 are also provided so as to be concentric with the placement surface 33. Further, for example, three lifting pins 38 (only two are shown in FIGS. 3 and 6) are provided on the stage 32 so as to move upward and downward with respect to the placement surface 33. The three lifting pins 38 are arranged around a center of the placement surface 33 so as to be separated from each other in a plan view (FIG. 1), and are disposed at positions at which central angles with respect to the center of the placement surface 33 are spaced at intervals of 120°. The lifting pins 38 are provided on a lifting plate 39a that is raised and lowered by a lifting mechanism 39 (FIG. 4), and are raised and lowered simultaneously. The lifting mechanism 39, the lifting plate 39a, and the lifting pins 38 are disposed to be sufficiently spaced apart from and independently of the tilting mechanism 7, the support 32b, and the stage 32 so as not to be affected by the tilting operation thereof. Therefore, even when the tilting mechanism 7 tilts, the lifting pins 38 may be raised and lowered along a vertical direction.

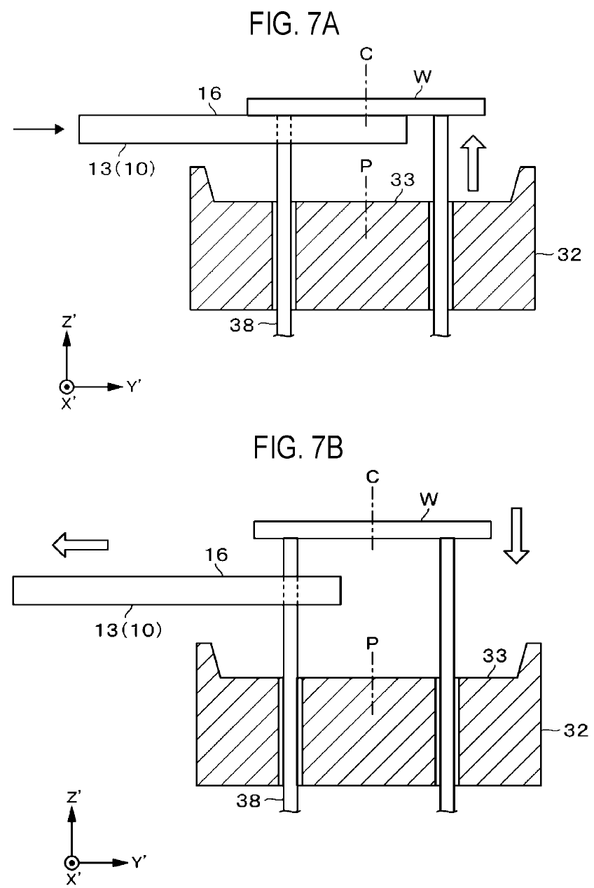

FIGS. 7A and 7B are vertical sectional side views showing the holder 16 and the lifting pins 38 during the placement of the substrate W. When placing the substrate W on the stage 32, the transfer mechanism 10 causes the holder 16 holding the substrate W to wait in advance at a standby position outside the gate valve G1. Then, as shown in FIG. 7A, the transfer mechanism 10 linearly advances the upper arm member 13 to enter the processing container 31 and positions the holder 16 at a preset "set position." The set position will be described later. Next, the protruding lifting pins 38 push up and support a back surface of the substrate W to receive the substrate W. At this time, in order to avoid interference with the holder 16, the lifting pins 38 are provided at positions that, in a plan view, pass through an inner space of the U-shaped holder 16.

Next, as shown in FIG. 7B, when the holder 16 moves in a direction opposite to the direction in which it entered the processing container 31 and is withdrawn from the processing container 31, the lifting pins 38 are lowered to place the substrate W on the placement surface 33 of the stage 32. Thereafter, when a film formation process performed by the film formation module 104 is completed, through an operation opposite to that performed during the placement described above, the lifting pins 38 deliver the substrate W from the stage 32 to the holder 16, and the holder 16 is withdrawn from the processing container 31. In this manner, the lifting pins 38 are capable of delivering the substrate W between the transfer mechanism 10 and the stage 32.

In the above-described placement operation, the set position of the holder 16 needs to be a position at which the substrate W delivered to the stage 32 is placed within the placement surface 33. In the first embodiment, the set position of the holder 16 is set such that the center C of the substrate W held by the holder 16 is aligned with a center P of the placement surface 33 in a plan view. However, in the substrate processing apparatus 1, the controller 5 and the drive controller 15 do not have accurate knowledge of the exact position of the center P of the placement surface 33. For example, when the processing container 31 is open and maintenance is performed on the stage 32 or the lifting pins 38, the position of the center of the stage 32, or the position of the substrate W delivered to the stage 32 via the lifting pins 38, may change.

For this reason, before starting the film formation process, the substrate processing apparatus 1 specifies the center P of the placement surface 33 in advance. Then, in order to specify a substrate delivery destination position (target position) at which the holder 16 is positioned above the center P and the substrate W may be delivered to the placement surface 33 via the lifting pins 38, and to set this target position to coincide with the above-described set position, it is necessary to perform teaching on the drive controller 15. For example, it is assumed that the substrate W has a diameter of 300 mm, the placement surface 33 has a diameter of 302 mm, and the tapered surface 34a has a width of 0.35 mm. In this case, when the substrate W is delivered to a position where the center of the substrate W is offset by only 1.4 mm from the center P of the placement surface 33, the film formation is performed while the substrate W remains riding on the edge portion 34. When the film formation is performed on the substrate W in such a state where the entire rear surface of the substrate W is not in contact with the placement surface 33, there is a risk that, for example, in-plane uniform temperature control cannot be achieved, resulting in reduced uniformity of the thickness of the formed film, or that a film may be formed even on the rear surface of the substrate W. Therefore, it is important to accurately specify the center P of the placement surface 33 and perform the teaching.

In this regard, for example, a method may be considered in which the processing container 31 is open, an operator measures the exact position of the center P of the placement surface 33, manually places the substrate W such that the center of the substrate W coincides with the measured center P, and performs the teaching based on a result of the substrate W being received by the holder 16. Alternatively, instead of placing the substrate W, a method may be considered in which a jig defining the target position is placed inside the processing container 31, and the teaching is performed by pressing the holder 16 against the jig. However, these methods involve operations performed with the processing container 31 in an open state, and therefore there is a risk that particles may enter and remain inside the processing container 31. In addition, performing operations by an operator requires operations of decreasing in internal temperature of the processing container 31 and increasing an internal pressure of the processing container 31. This increases non-operating time (idle time) of the substrate processing apparatus 1, even though the decrease in the internal temperature and the increase in the internal pressure are not originally required except during maintenance. Further, since the teaching performed at room temperature after the decrease in the internal temperature does not include the effects of thermal expansion of the stage 32 and the lifting pins 38, it is difficult to perform highly accurate teaching. Further, since the tilt of the lifting pins 38 may slightly differ between teaching performed in an atmospheric environment and film formation process performed in a vacuum environment, it is also difficult to perform highly accurate teaching. In view of these issues, the inventors of the present application have developed a teaching method that may be performed without opening the processing container 31 and without performing the operation of decreasing the internal temperature and increasing the internal pressure of the processing container 31.

Returning to the description of the configuration of the substrate processing apparatus 1, as illustrated in FIG. 4, the controller 5 is connected to the tilting mechanism 7, the position detector 4, the drive controller 15, the pulse encoder 17, and the lifting mechanism 39, and cooperates therewith to perform operations from the specification of the target position to the teaching. The controller 5 is constituted with a computer including a central position specificator 51 for calculating the center P of the placement surface 33, a program storage 52 that stores various programs for operating respective components of the substrate processing apparatus 1, a CPU 53, and a memory 54. A program for transferring a wafer is configured such that the holder 16 holds the substrate W and transfers the same to respective set positions of the film formation modules 101 to 104, and specifically includes a group of operations for calculating a trajectory of the holder 16. Further, a program for specifying the delivery destination position of the holder 16 includes a plurality of operation groups for executing various processes as will be described later.

The various programs are installed in the program storage 52 via a storage medium such as a USB memory or a DVD-ROM, for example. Based on signals from the pulse encoder 17, the controller 5 manages operation control of the transfer mechanism 10 by the drive controller 15 so that the holder 16 moves in accordance with a recipe constituting a processing program for the substrate W. In the substrate processing apparatus 1 as described above, the controller 5, the transfer mechanism 10, the drive controller 15, and the pulse encoder 17 constitute a substrate transfer device of the present disclosure in which teaching based on a result of specifying the delivery destination position is executed.

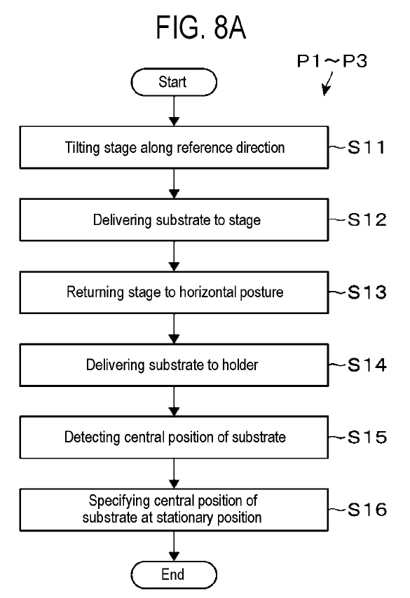

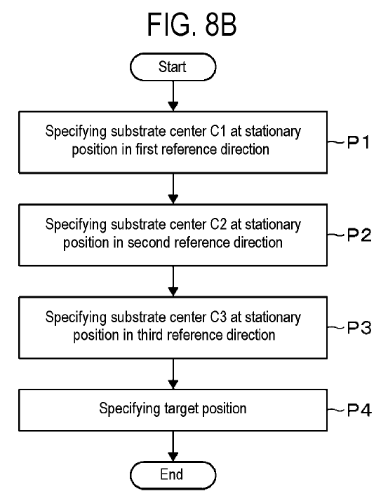

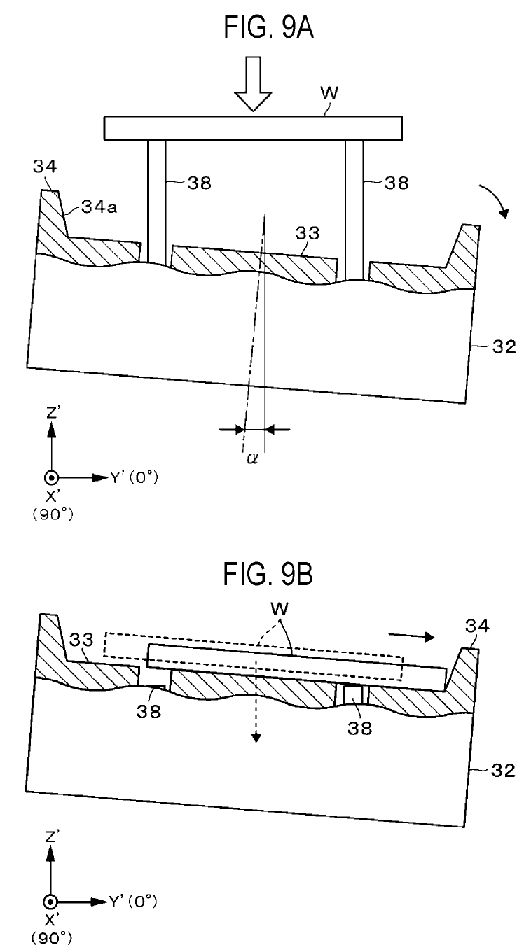

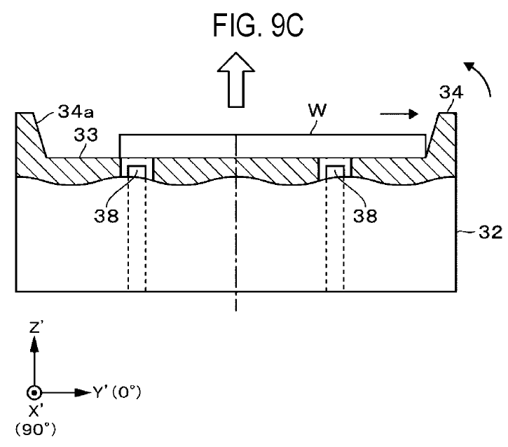

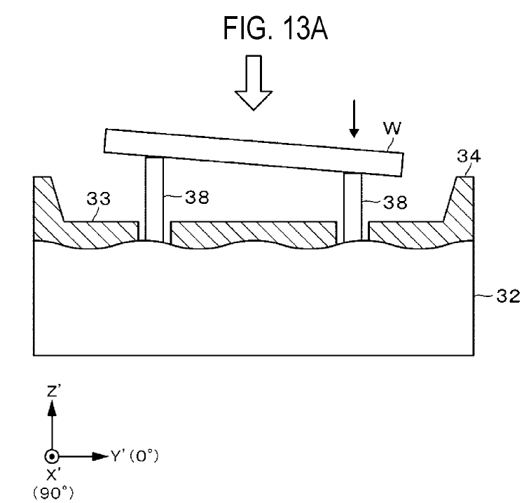

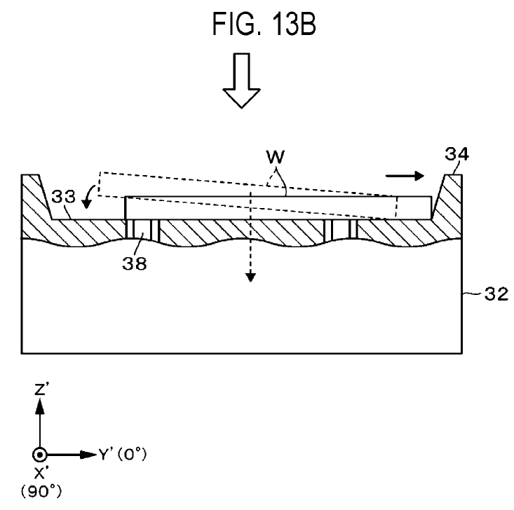

The specification of the delivery destination position will now be described. FIG. 8A is a flowchart illustrating a cyclic process performed in the delivery destination position determination operation of the first embodiment, and FIG. 8B is a diagram illustrating a procedure of the delivery destination position determination operation. FIGS. 9A and 9B are partial vertical sectional side views of the stage 32, illustrating the delivery destination position specifying operation of the first embodiment. FIGS. 10A to 10D are plan views of the stage 32 and the substrate W, illustrating the specifying operation. In these figures, a reference direction is indicated by showing a lowering direction at a portion lowered the most at the periphery of the placement surface 33, relative coordinates with a reference point at the center P of the placement surface 33 are indicated by a one-dot chain line, and the center of the substrate W is indicated by a black dot. The centers C0 and C1 to C3 shown in FIGS. 10A to 10D indicate positions in a state where the placement surface 33 is maintained in a horizontal posture without being tilted. In these figures, solid arrows indicate trajectories, and hollow arrows indicate directions of subsequent movement. The same applies to FIGS. 13A and 13B relating to a second embodiment to be described later.

First, a principle of specifying the delivery destination position will be described. As illustrated in FIGS. 9A and 10A, a Y'-axis direction, which is one direction in an X-Y plane for tilting the stage 32, is set as a reference direction. As described above, the stage 32 is tilted along the Y'-axis direction (Step S11: tilting operation). While maintaining this tilted state, the holder 16 transfers the substrate W to a preset initial set position C0 and receives the substrate W by the raised lifting pins 38 (FIGS. 9A and 10A). Next, the lifting pins 38 are lowered to deliver the substrate W to the tilted placement surface 33 (Step S12: substrate transfer operation; FIG. 9B). Thus, the substrate W, which is placed at the initial set position C0 by the holder 16 and delivered to the lifting pins 38, needs to be placed within the tilted placement surface 33. Therefore, the initial set position C0 needs to be a position at which the substrate W may be placed on the placement surface 33 in a horizontal posture without tilting, and may also be placed on the placement surface 33 even when tilted. The initial set position C0 may be predicted in advance based on design drawings of the film formation module 104 and the stage 32, and may be verified by preliminary tests or the like to satisfy the above conditions.

When placed on the placement surface 33, the substrate W supported by the lifting pins 38 in a horizontal posture first comes into contact with the tilted placement surface 33 on a side opposite to the Y'-axis direction, and thereafter, when the lifting pins 38 retract into the stage 32, the entire surface of the substrate W is positioned near the placement surface 33 (see the broken line in FIG. 9B). Then, the substrate W slides and moves along the Y' axis on the placement surface 33 tilted in the Y'-axis direction by gravity, and comes into contact with and stops at the tapered surface 34a, that is, the inner periphery of the edge portion 34 (see the solid line in FIGS. 9B, and 10B, ). In order to allow the substrate W to sufficiently slide in the reference direction (the Y'-axis direction), it is preferable that, when the substrate W is placed on the placement surface 33, a relatively large amount of gas molecules remains on a lower surface of the substrate W approaching the placement surface 33, so that viscous resistance acts. Accordingly, for example, when the substrate W is delivered to the placement surface 33, it is preferable to increase the internal pressure of the processing container 31 in advance to about 100 Pa, thereby increasing an amount of gas molecules remaining between the lower surface of the substrate W and the placement surface 33.

Thus, a side surface of the substrate W at a stationary position is in contact with the inner periphery of the edge portion 34, and the entire lower surface of the substrate W is in contact with the placement surface 33. The stationary position of the substrate W is, for example, a position located in the Y'-axis direction from the initial set position C0 and in contact with the periphery of the placement surface 33 (see FIG. 10B). The center C1 of the substrate W at the stationary position is measured by the position detector 4 (Step S13). The center C1 is considered to be located on a circle S (see the broken line in FIG. 10B), which represents a set of centers of the substrate W arranged so as to be in contact with respective positions on the inner periphery of the placement surface 33. The center of the circle S is considered to coincide with the center P of the placement surface 33. Therefore, by measuring the positions of point C1 on the circumference of the circle S and two other points C2 and C3 (P1 to P3 in FIG. 8A), and determining the center of a circle passing through these different points C1 to C3, a final delivery destination position may be specified (P4).

Based on the concept described above, a target position determination operation of the holder 16 and a teaching operation in the substrate transfer device according to the first embodiment will be described. In this example, the first to third reference directions are set to be the 0° direction, which is the previously described Y'-axis direction, and two directions offset by 120° and 240° from the 0° direction, respectively, and the placement surface 33 is inclined along each reference direction. Then, the substrate W delivered to the placement surface 33 inclined along each reference direction is caused to slide toward a lower side of the tilt, and the positions of the centers C1 to C3 of the substrate W that has reached the stationary position are specified respectively (Processes P1 to P3 in FIG. 8B).

As an overall outline, the target position determination operation in the first embodiment is performed in the following order: specifying the position of the center C1 of the substrate W slid in the first reference direction of 0° (Process P1 in FIGS. 8B;9B and 10B ), specifying the position of the center C2 of the substrate W slid in the second reference direction of 120° (Process P2; FIG. 10C), specifying the position of the center C3 of the substrate W slid in the third reference direction of 240° (Process P3; FIG. 10D), and specifying coordinates of the target position (Process P4). Thereafter, the target position is determined based on the positions of the centers C1 to C3 of the substrate W at the measured stationary positions. FIG. 10A is a flowchart illustrating a cycle including sliding the substrate W in each reference direction and detecting the positions of the centers C1 to C3 of the substrate W at the stationary positions (hereinafter referred to as a cyclic operation). The target position is determined based on the positions of the centers C1 to C3 of the substrate W at the stationary positions specified in the cyclic operation for each reference direction.

Next, the operation of specifying the center C1, which corresponds to Process P1, will be described in detail with reference to FIG. 8B. Process P1 is an operation of specifying the position of the center C1 of the substrate W that has reached the stationary position in the first reference direction of 0°. In this example, first, the substrate W in the transfer container K transferred to the load port 21 (FIG. 1) is transferred by the transfer mechanism 25 in the atmospheric-pressure transfer chamber 22 via the alignment chamber 26 and then to the load lock chamber 23. The substrate W is not limited to one transferred in the transfer container K, and may be placed in advance in the atmospheric-pressure transfer chamber 22, or a dummy substrate having the same shape as the substrate W may be used.

The substrate W adjusted to face a predetermined direction in the alignment chamber 26 is placed on a stage (not shown) in the load lock chamber 23 by the transfer mechanism 25. The substrate W placed on the stage of the load lock chamber 23 is arranged such that, for example, a 0° peripheral end (in this example, a tip of a notch cutout) is positioned at a location farthest from the gate valve 29 on the vacuum transfer chamber 24 side. The load lock chamber 23 delivers the substrate W oriented in this manner to the holder 16 of the transfer mechanism 10. The held substrate W is oriented such that the 0° peripheral end is positioned on a leading end side of the holding region of the holder 16, and the held substrate W is positioned at a preset appropriate holding position with respect to the holder 16.

Next, the transfer mechanism 10 positions the holder 16 holding the substrate W above the measurement region A1 (FIG. 5). The position calculator 44 measures the position (x11, y11) of a center c11 of the substrate W using the line sensors 41 to 43 and stores the measured position in the memory 54. The position (x11, y11) of the center c11 of the substrate W positioned at the appropriate holding position is, for example, (0, 0) in the relative coordinate system illustrated in FIG. 5. Further, since the position of the substrate W is specified in the alignment chamber 26 and the position (x11, y11) of the center c11 of the substrate W before being placed on the stage 32 is arranged substantially accurately at the appropriate holding position, the measurement by the position calculator 44 may be omitted.

On the other hand, in one of the film formation modules 101 to 104 for determining the target position of the holder 16 (in this example, the film formation module 104), the stage 32 is tilted toward the first reference direction of 0° by the tilting mechanism 7 (Step S11 in FIG. 8A, Operation (a): an operation of tilting the placement surface, FIG. 9A). The tilt angle α (FIG. 9A) of the stage 32 at this time is set to, for example, 0.1° or more, and may be appropriately set depending on the ease with which the substrate W slides on the placement surface 33. Then, the substrate W whose the position of the center c11 has been measured by the position calculator 44 is transferred to the stage 32 of the film formation module 104. Specifically, when the gate valve G1 of the film formation module 104 is open, based on the substrate transfer program described above, the holder 16 holding the substrate W is positioned above the stage 32 at the above-described initial set position C0, and then the substrate W is transferred to the placement surface 33 via the lifting pins 38 (Step S12, Operation (b): an operation of delivering the substrate to the stage, the substrate W indicated by a broken line in FIGS. 9B, and 10A, ). As a result, the substrate W slides on the placement surface 33 in the first reference direction (Y'-axis direction) and then reaches the stationary position in contact with the inner periphery of the edge portion 34 (the substrate W indicated by a solid line in FIGS. 9B,10B ).

Next, while maintaining the substrate W at the stationary position, the stage 32 is returned to a horizontal posture (Step S13, FIG. 9C). Thereafter, the lifting pins 38 are raised from the placement surface 33 returned to the horizontal posture, and the substrate W at the stationary position is delivered to the holder 16 (Step S14, Operation (c): an operation of receiving the substrate by the transfer arm). By performing the above-described operations, a positional deviation L1 (see FIG. 10B) from the initial set position to the stationary position may be measured with high accuracy on the placement surface 33, which is in a horizontal posture similar to that during the film formation process. As will be described later, the specification of the positional deviation L1, which is a vector representing displacement, is performed by the position detector 4.

At this time, after the lifting pins 38 are moved upward to raise the substrate W from the placement surface 33, the substrate W is delivered to the holder 16 positioned again at the initial set position C0. The substrate W thus delivered is held by the holder 16 while sliding in the first reference direction on the placement surface 33 from the appropriate holding position and moving horizontally, that is, while maintaining the positional deviation L1. Next, in order to detect the deviation L1, the holder 16 holding the substrate W is positioned in the measurement region A1, and the position (x'11, y'11) of a center c'11 of the deviated substrate W is detected (Step S15, Operation (d): an operation of detecting a position of the substrate). The central position specificator 51 calculates the deviation L1, which is a vector, by taking a difference between a position coordinate of the center c'11 of the substrate W, which corresponds to a new holding position, and a position coordinate of the center c11 of the substrate W, and then specifies the position of the center C1 by correcting the initial set position C0 by the deviation L1 (Step S16).

Next, the Process (P2) of specifying the position of the center C2 of the substrate W that has reached the stationary position in the second reference direction of 120° is performed. First, the stage 32 is tilted by the tilting mechanism 7 toward the 120° direction (Step S11, FIG. 10C). Then, the substrate W whose the position of the center c11 has been measured by the position calculator 44 is transferred again by the holder 16 to the initial set position C0 above the stage 32 of the film formation module 104. Thereafter, the substrate W is delivered onto the placement surface 33 via the lifting pins 38 (Step S12, FIG. 10C).

When placing the substrate W at the initial set position C0 and when the holder 16 supports the substrate W at the appropriate holding position, the initial set position may be set to be the same initial set position C0 as that used in Process P1 of specifying the position of the center C1. However, in the first embodiment, during the cyclic operation of Process P1, the substrate W is held in a state deviated from the appropriate holding position. As a first method for addressing such a situation, the initial set position C0 may be set by holding the substrate W again. For example, a method may be employed, which includes advancing the holder 16 into the film formation module 104 again after the position of the center c'11 of the substrate W has been measured in the measurement region A1, and holding the substrate W again with the lifting pins 38. Before holding the substrate W again, the holder 16 is moved to the initial set position, which is a previous set position, the substrate W is delivered to the lifting pins 38, and the holder 16 is shifted by an amount corresponding to the displacement (that is, the deviation L1) of the substrate W with respect to the holder 16 to perform a position correction. Thereafter, when the substrate W is delivered from the lifting pins 38 to the holder 16 for which the position correction has been performed, the substrate W may be positioned at the appropriate holding position.

As the first method, in addition to the example using the film formation module 104 as described above, the transfer mechanism 25 having the edge grip function described with reference to FIG. 2 may be used. It is possible to correct the position of the substrate W by delivering the substrate W from the transfer mechanism 10 to the transfer mechanism 25 and positioning the substrate W by means of the regulating protrusion 25a and the pressing portion 25b provided on the holder 25m shown in FIG. 2. Further, as a variation of the first method, in a case in which orientation correction is required due to rotation of the substrate W about the center on the stage, the orientation and position of the substrate W may be corrected by delivering the substrate W to the alignment chamber 26 and the transfer mechanism 25.

In a second method to eliminate the influence of the deviation from the appropriate holding position, the substrate W may be delivered to the lifting pins 38 at the initial set position C0 without holding the substrate W again. In this case, by placing the substrate W at a position that cancels the deviation L1 from the initial set position C0 specified for the first reference direction, the substrate W may be directly placed at the initial set position C0.

The substrate W placed at the initial set position C0 by the above-described methods is delivered to the tilted placement surface 33 in the same manner as in Process P1 described above. Then, after the substrate W slides on the placement surface 33 and reaches the stationary position, the stage 32 is returned to a horizontal posture and the substrate W is received by the holder 16. Thereafter, the central position of the substrate W is detected in the measurement region A1, and the position of the center C2 of the substrate W at the stationary position in the second reference direction (the 120° direction) is specified (Steps S12 to S16; FIG. 10C). Then, in the same manner as in Processes P1 and P2 described above, Process P3(Steps S11 to S15) for specifying the position of the center C3 of the substrate W at the stationary position is also performed for the 240° direction, which is the third reference direction, to specify the center C3 (Step S16, FIG. 10D).

Subsequently, a portion of the center of the circle S connecting the different centers C1 to C3 specified as described above is calculated, the position of the center P of the placement surface 33 that is substantially identical to the center is specified, and a target position is determined (P4). The central position specificator 51 determines the target position as a set position of the holder 16 for the drive controller 15 (an operation of setting the target position). In this way, the target position of the film formation module 104 is taught to the drive controller 15.

The determination of the target position and the teaching described above may be performed on the film formation modules 101 to 103 other than the film formation module 104, and may additionally be performed as appropriate when maintenance is required for any of the modules 101 to 104. As described above, the determination of the target position and the teaching are performed during a period in which substrate processing such as film formation is not being performed. After the determination of the target position and the teaching for each of the film formation modules 101 to 104 are completed, film formation process is started in the substrate processing apparatus 1. In the substrate processing apparatus 1 according to the first embodiment, a transfer path of the substrate W during the film formation process is as follows: the transfer container K → the load port 21 → the alignment chamber 26 → the atmospheric-pressure transfer chamber 22 → the vacuum transfer chamber 24 → one of the film formation modules 101 to 104. The substrate W, which has been subjected to the film formation process in any one of the film formation modules 101 to 104, is transferred in the reverse order of the above-described sequence and returned to the transfer container K.

When transferring the substrate W to any one of the film formation modules 101 to 104 along the transfer path described above, as illustrated in FIGS. 7A and 7B, the holder 16 holding the substrate W is moved to the set position taught by the drive controller 15. The substrate W supported by the holder 16 is positioned above the center P of the placement surface 33, lowered via the lifting pins 38 toward the center P of the horizontal placement surface 33 without being tilted, and placed on the placement surface 33 where the substrate W is subjected to the film formation process.

As described above, in the teaching method used in the substrate transfer device according to the first embodiment, the film formation module 104 is provided with the tilting mechanism 7 for tilting the stage 32. Further, one reference direction is arbitrarily selected from at least three different reference directions, and the stage 32 is tilted in the selected reference direction by the tilting mechanism 7. Next, the substrate W placed at the set position C0 is delivered to the placement surface 33 via the lifting pins 38, slides along the reference direction, and is stopped when coming into contact with the inner periphery of the edge portion 34. Thereafter, while maintaining the substrate W at the stationary position, the placement surface 33 is returned to a horizontal posture, the substrate W is received by the holder 16 via the lifting pins 38, and the center C1 of the substrate W at the stationary position is detected using the position detector 4. By performing this cyclic operation for each of the remaining reference directions, the centers of the substrate W at the stationary positions in these reference directions are detected, and the center P of the stage 32 may be specified based on a circle formed by connecting the centers C1 to C3. As described above, according to the present embodiment, the position of the center P of the stage 32 may be automatically specified in a simple manner in a short period of time while maintaining the vacuum transfer chamber 24 and the film formation modules 101 to 104 in the vacuum atmosphere and maintaining the temperatures thereof. The center P of the stage 32 specified in this manner may be set as the target position when delivering the substrate W from the holder 16 to the stage 32.

### Modification

In the first embodiment, after tilting the stage 32 by the tilting mechanism 7, the substrate W is delivered to the tilted placement surface 33 via the lifting pins 38. However, the teaching method of the present disclosure is not limited to such a procedure. For example, before tilting the stage 32, the substrate W may be delivered from the holder 16 to the lifting pins 38, and subsequently, the stage 32 may be tilted and the lifting pins 38 may be lowered to deliver the substrate W to the tilted placement surface 33. Alternatively, for example, before tilting the stage 32, the substrate W may first be delivered to the lifting pins 38, the lifting pins 38 may be lowered to deliver the substrate W to the placement surface 33 which has not yet tilted, and subsequently, the placement surface 33 may be tilted. In this state, the substrate W may be slid in a tilted direction while coming into contact with the placement surface 33. In this case, since the substrate W on the placement surface 33 is in contact with the placement surface 33 and is less likely to slide, the tilt angle may be set to a relatively large level.

In the first embodiment, the first to third reference directions are set to 0°, 120°, and 240°, but the reference directions are not limited thereto. For example, three reference directions may be set at intervals of 120° based on a reference offset from 0°. Further, it is not essential to set three reference directions at intervals of 120°. Four reference directions may be set at intervals of 90°, or six reference directions may be set at intervals of 60° may be set. The intervals between reference directions also need not be uniform, and may be different from each other. That is, the reference directions may be freely set as long as a circle for specifying the center P of the stage 32 can be obtained from the positions of centers of the substrate W specified by repeatedly performing the above-described specifying operations multiple times,. Therefore, the reference directions for respective specifying operations may be different from each other.

In the first embodiment, in performing Processes P1 to P3 of specifying the centers C1 to C3 of the substrate at the stationary position in the first to third reference directions, the substrate W is placed at the same initial set position C0. Alternatively, the specifying operations may be performed by placing the substrate W at different positions each time. Even when the substrate W is placed at different initial set positions, the stationary position of the substrate W eventually reaches substantially the same position according to the reference direction. Therefore, the position of the center of the substrate W at the stationary position may be specified from positional deviation as long as the initial set position at which the substrate W is delivered for each reference direction can be detected.

In addition, when the substrate W actually slides on the placement surface 33, the substrate W may slide whine deviating from the reference direction or may slide while rotating. In such cases, the substrate W may stop at a position different from an intersection of the reference direction with the edge portion 34 (positions indicated by circled crosses in FIGS. 10B and 10C). Even in such cases, the center P of the stage 32 may be specified as long as the substrate W stops at different positions in contact with the inner periphery of the placement surface 33 in at least three specifying operations. Therefore, the tilt of the stage 32 is not particularly limited as long as the substrate W may slide on the placement surface 33 until reaching the stationary position. A tilt angle or tilt direction of the stage 32 may be changed while the substrate W is sliding.

In the first embodiment, the position and trajectory of the holder 16 are set with respect to the holding region, and the center of the holding region and the center C of the substrate W at the holding position are set so as to be aligned with each other. However, the center of the holding region and the center C of the substrate W at the holding position need not necessarily be aligned with each other. Although the teaching method according to the first embodiment is performed on the set positions of the film formation modules 101 to 104, the present disclosure is not limited thereto. For example, the teaching method may also be applied to set positions of the stage in the load lock chamber 23 or the like or to set positions of a spin chuck in a liquid processing module not illustrated in the present disclosure.

In the first embodiment, the substrate W is transferred by the transfer arm 10a, which is an articulated arm. However, other transfer mechanisms such as a transfer mechanism configured to move and transfer the substrate by magnetic levitation using electromagnets, may be employed. In the first embodiment, the edge portion 34 is provided with the tapered surface 34a. However, the tapered surface 34a may be omitted. An inner circumferential side of the edge portion 34 may be a vertical surface rising from the stage 32. The tilting mechanism 7 described in the first embodiment is merely an example, and the stage 32 may be tilted by another tilting mechanism.

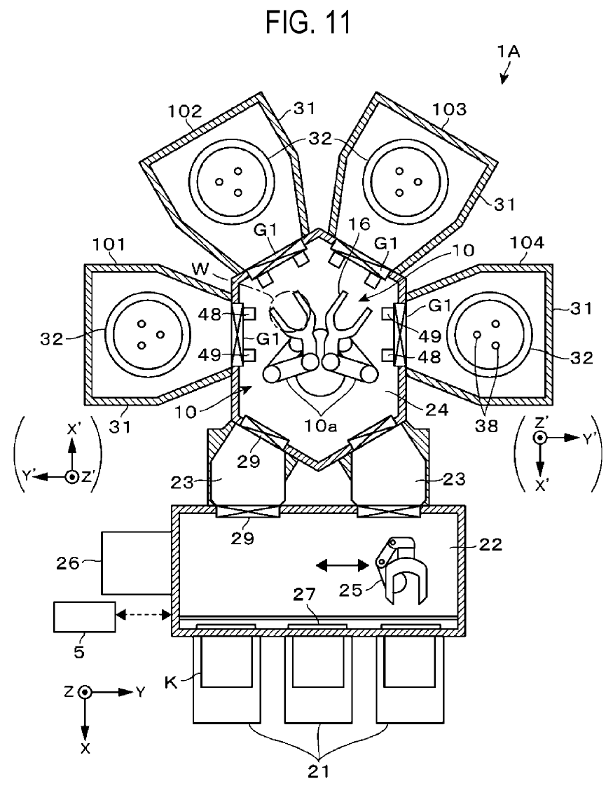

The present disclosure is not limited to measuring the positional deviation of the substrate W before and after placement by using the line sensors 41 to 43 as in the substrate processing apparatus 1 of the present disclosure. FIG. 11 is a plan view illustrating a modification of the substrate processing apparatus 1. In a substrate processing apparatus 1A, line sensors 48 and 49 having arrangements and numbers different from those of the line sensors 41 to 43 of the first embodiment are provided in the vacuum transfer chamber 24. The line sensors 48 and 49 are provided in a housing of the vacuum transfer chamber 24 in the same manner as the line sensors 41 to 43, and are respectively disposed on both sides of the gate valve G1 in front of each gate valve G1 of the film formation modules 101 to 104. With this configuration, light is blocked by 90°-side portions and 270°-side portions of the substrate W, which linearly passes through the loading/unloading opening of each of the film formation modules 101 to 104. Thus, the line sensors 48 and 49 may detect peripheral points (for example, four peripheral points) of the substrate W and may measure a position of the center c of the substrate W that has passed through the loading/unloading opening.

In addition, in the first embodiment, the lifting pins 38 and the lifting mechanism 39 are independently arranged to be spaced sufficiently apart from the tilting mechanism 7, the support 32b, and the stage 32 so as not to be affected by the tilting operation. However, the lifting pins 38 and the lifting mechanism 39 may be configured so as to be affected by the tilting operation. Specifically, for example, when the lifting plate 39a and the lifting mechanism 39 are constrained in the lifting direction by the support 32b along the support 32b, it is assumed that the lifting plate 39a and the lifting mechanism 39 tilt in conjunction with the tilting of the support 32b. Even in such a case, it is sufficient that, when the stage 32 is tilted, the lifting pins 38 may appropriately receive the substrate W without dropping the substrate W and may place the substrate W in the plane of the placement surface 33.

As another configuration example for raising and lowering the lifting pins 38, it is conceivable that the lifting plate 39a and the lifting mechanism 39 shown in FIGS. 4 and 6 are not provided, and for example, each lifting pin 38 is suspended from the stage 32. In this case, the plurality of lifting pins 38 are provided so as to independently pass through through-holes of the stage 32. Each lifting pin 38 is configured such that an upper portion thereof has an increased diameter and is engaged with the through-hole of the stage 32, thereby being suspended from the stage 32. Further, for example, when each actuator 78 is extended by an equal width and the stage 32 is disposed at an upper position, the lifting pins 38 remain suspended from the stage 32 and do not protrude from the placement surface 33. On the other hand, when each actuator 78 is retracted by an equal width and the stage 32 is disposed at a lower position, the lower ends of the lifting pins 38 are brought into contact with the bottom of the processing container 31 and are pushed upward, thereby protruding from the placement surface 33.

### Second Embodiment

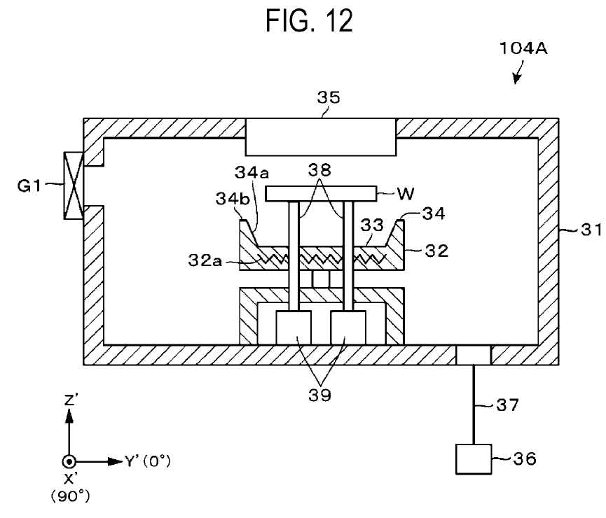

In the second embodiment, instead of sliding the substrate W toward the stationary position by placing the substrate W on the tilted stage 32 in the first embodiment, the substrate is slid by placing the substrate W in a tilted state on the placement surface 33 in, for example, a horizontal state. FIG. 12 is a vertical sectional side view illustrating a film formation module according to the second embodiment. In the following description of the second embodiment, differences from the first embodiment will be mainly described, and the same constituent elements will be indicated by the same reference numerals as those in the first embodiment and redundant descriptions thereof are omitted. In a film formation module 104A of the second embodiment, the tilting mechanism 7 and the lifting plate 39a are not provided, and the lifting pins 38 are individually raised and lowered with respect to the stage 32 in a fixed state. To do this, for example, individual lifting mechanisms 39 are provided below the lifting pins 38, respectively. Accordingly, when the substrate W is delivered to the placement surface 33 (Step S12), height positions of the lifting pins 38 are made different so that the substrate W is placed on the placement surface 33 while being titled. As a result, the substrate W is pushed out due to the influence of gas present between the substrate W and the placement surface 33, thereby allowing the substrate W to slide in the first to third reference directions. As in the first embodiment, in the example of the second embodiment as well, the centers C1 to C3 of the substrate at the stationary position may be specified.

FIGS. 13A and 13B are partial vertical sectional side views of the stage 32, which illustrate an operation of specifying a delivery destination position according to the second embodiment, and illustrate an example in which the substrate W slides while being tilted in the Y'-axis direction. When delivering the substrate W to the placement surface 33 (Step S12), first, three lifting pins 38 are positioned at the same upper height position and receive the substrate W in a horizontal posture from the holder 16. Then, as illustrated in FIG. 13A, the substrate W is tilted to some extent by primarily lowering two lifting pins 38 disposed on one side of the Y'-axis direction, and subsequently, one lifting pin 38 disposed on the opposite side of the Y'-axis direction is lowered. For example, speeds at which the three lifting pins 38 are lowered are set equal to each other. Accordingly, the three lifting pins 38 may deliver the substrate W, which is tilted toward the Y'-axis direction, onto the placement surface 33.

As illustrated in FIG. 13B, the substrate W tilted in the Y'-axis direction (as indicated by a broken line) first comes into contact with the placement surface 33 at an end portion in the Y'-axis direction, and subsequently, an end portion on the opposite side of the Y'-axis direction is lowered. At this time, the substrate W is pushed out by gas between the lower surface of the substrate W on the opposite side of the Y'-axis direction and the placement surface 33, and slides in the Y'-axis direction. Further, as in the first embodiment, the position of the center C1 of the substrate W (as indicated by the solid line in FIG. 13B) at the stationary position after sliding in the Y'-axis direction may be specified.

When sliding the substrate W in the reference directions of 120° and 240° in the same manner as in the first embodiment, two lifting pins 38 on the opposite side of the Y'-axis direction and in the Y'-axis direction and the X'-axis direction, and two lifting pins 38 on the opposite side of the Y'-axis direction and in the Y'-axis direction and the opposite side of the X'-axis direction may be lowered first. Alternatively, in a case in which the three reference directions are respectively set toward the directions in which the lifting pins 38 are arranged, among the three lifting pins 38, one lifting pin 38 in the reference direction may be lowered first, and then the remaining two lifting pins 38 may be lowered, thereby allowing the substrate W to be tilted and slid in the reference direction. Lowering timings may be individually set so that the height positions of the three lifting pins 38 are different from each other. Alternatively, without providing a difference in the lowering timings of the three lifting pins 38 as described above, by making lowering speeds of the lifting pins 38 different from each other, the substrate W may be tilted and slid on the placement surface 33. Four or more lifting pins 38 may be provided. Further, in the present disclosure, the operation of specifying the destination position may be performed by combining the tilting of the substrate W by the lifting pins 38 in the second embodiment with the tilting of the stage 32 in the first embodiment.

According to the present disclosure in some embodiments, it is possible to teach a set position of a transfer arm to appropriately place a substrate on a stage of a substrate processing apparatus.

While certain embodiments have been described, these embodiments have been presented by way of example only, and are not intended to limit the scope of the disclosures. Indeed, the embodiments described herein may be embodied in a variety of other forms. Further, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of teaching a substrate transfer device,
wherein the substrate transfer device includes a transfer arm configured to transfer a substrate, a drive mechanism configured to move the transfer arm, and a drive controller configured to control the drive mechanism such that the transfer arm moves to a preset set position, and
wherein when the substrate is transferred by the transfer arm to a stage including a placement surface on which the substrate is placed, an edge portion is provided so as to protrude from the placement surface along a periphery of the placement surface, and at least three lifting pins configured to move upward and downward with respect to the placement surface are provided and configured to deliver the substrate with respect to the transfer arm while holding the substrate,
the method comprises:
executing a cycle with respect to each of at least three reference directions which are set so as to extend in different directions from a center of the placement surface toward the periphery of the placement surface, the cycle including:
(a) an operation of tilting at least one of the placement surface or the substrate held by the at least three lifting pins such that, along one reference direction selected from the at least three reference directions, a height position of the periphery is lower than a height position of the center;
(b) an operation of lowering the at least three lifting pins to deliver the substrate to the stage;
(c) an operation of, after the substrate delivered to the stage moves onto the placement surface along the one reference direction and reaches an inner periphery of the edge portion, raising the at least three lifting pins such that the transfer arm receives the substrate; and
(d) an operation of detecting a position of the substrate received from the stage by the transfer arm;
determining a target position at which the substrate is to be delivered from the transfer arm to the stage, based on results of detecting positions of the substrate after being moved along all of the at least three reference directions; and
setting the target position to the set position of the transfer arm for the drive controller.

2. The method of claim 1, wherein the stage includes a tilt adjustment mechanism configured to adjust a tilt of the stage, and
wherein, in the operation (a), the placement surface is tilted by adjusting the tilt of the stage using the tilt adjustment mechanism.

3. The method of claim 1, wherein the at least three lifting pins includes a plurality of lifting mechanism configured to adjust height positions of the at least three lifting pins, respectively, and
wherein, in the operation (a), the substrate is tilted by setting height positions of the at least three lifting pins at which the substrate is held by the at least three lifting pins different from each other using the plurality of lifting mechanisms.

4. The method of claim 1, wherein the stage has a circular planar shape.

5. The method of claim 4, wherein the substrate has a circular planar shape, and
wherein, in the determining the target position, the target position is determined such that a center of the substrate coincides with a center of the stage.

6. The method of claim 5, wherein the substrate has a circular planar shape, and
wherein, in the operation (d), the center of the substrate held by the transfer arm is obtained, and the center of the stage serving as the target position is determined based on a circle connecting centers of the substrate after being moved along all of the at least three reference directions.

7. The method of claim 1, wherein the stage is provided inside a processing container in which the substrate is processed.

8. The method of claim 7, wherein an interior of the processing container constitutes a film formation processing module configured to perform a film formation process on the substrate.

9. The method of claim 8, wherein the teaching is performed during a period in which the substrate is not being processed.

10. An apparatus for processing a substrate, comprising:
a processing module including a processing container in which the substrate is processed;
a transfer module configured to be moved by a drive mechanism and including a transfer arm configured to transfer the substrate;
a drive controller configured to control the drive mechanism;
a position detection mechanism configured to detect a position of the substrate held by the transfer arm; and
a controller,
wherein a stage is provided inside the processing container, the stage having a placement surface on which the substrate is placed, an edge portion is provided so as to protrude from the placement surface along a periphery of the placement surface, and at least three lifting pins configured to move upward and downward with respect to the placement surface are provided and configured to deliver the substrate with respect to the transfer arm, and
wherein the controller is configured to output a control signal to execute:
when the substrate is transferred by the transfer arm to a stage, executing a cycle with respect to each of at least three reference directions which are set so as to extend in different directions from a center of the placement surface toward the periphery of the placement surface, the cycle including:
(a) an operation of tilting at least one of the placement surface or the substrate held by the at least three lifting pins such that, along one reference direction selected from the at least three reference directions, a height position of the periphery is lower than a height position of the center;
(b) an operation of lowering the at least three lifting pins to deliver the substrate to the stage;
(c) an operation of, after the substrate delivered to the stage moves onto the placement surface along the one reference direction and reaches an inner periphery of the edge portion, raising the at least three lifting pins such that the transfer arm receives the substrate; and
(d) an operation of detecting a position of the substrate received from the stage by the transfer arm;
determining a target position at which the substrate is to be delivered from the transfer arm to the stage, based on results of detecting positions of the substrate after being moved along all of the at least three reference directions; and
setting the target position to the set position of the transfer arm for the drive controller.

11. The apparatus of claim 10, wherein the stage includes a tilt adjustment mechanism configured to adjust a tilt of the stage, and
wherein, in the operation (a), the placement surface is tilted by adjusting the tilt of the stage using the tilt adjustment mechanism.

12. The apparatus of claim 10, wherein the at least three lifting pins includes a plurality of lifting mechanism configured to adjust height positions of the at least three lifting pins, respectively, and
wherein, in the operation (a), the substrate is tilted by setting height positions of the at least three lifting pins at which the substrate is held by the at least three lifting pins different from each other using the plurality of lifting mechanisms.
